(19) United States
(12) Patent Application Publication
(10) Pub. No.: US 2008/0185694 A1
(43) Pub. Date: Aug. 7, 2008

(54) Processes of Manufacturing Portable Electronic Storage Devices Utilizing Lead Frame Connectors

(75) Inventors: Siew Sin Hiew, San Jose, CA (US); Jim Chin-Nan Ni, San Jose, CA (US); Abraham Chih-Kang Ma, Fremont, CA (US); Ming-Shiang Shen, Taipei Hsien (TW)

Correspondence Address: ROGER H. CHU, 19499 ERIC DRIVE, SARATOGA, CA, 95070, US

(73) Assignee: SUPER TALENT ELECTRONICS, INC., San Jose, CA (US)

(21) Appl. No.: 11/872,588

(22) Filed: Oct. 15, 2007

Related U.S. Application Data
(63) Continuation-in-part of application No. 11/773,830, filed on Jul. 5, 2007.
Application No. 11/773,830 is a continuation-in-part of application No. 11/831,888, filed on Jul. 31, 2007.
Application No. 11/831,888 is a continuation-in-part of application No. 11/309,594, filed on Aug. 28, 2006, now Pat. No. 7,383,362.
Application No. 11/309,594 is a continuation-in-part of application No. 10/707,277, filed on Dec. 2, 2003, now Pat. No. 7,103,684.
Application No. 10/707,277 is a continuation-in-part of application No. 11/624,667, filed on Jan. 18, 2007.
Application No. 11/624,667 is a continuation-in-part of application No. 09/478,720, filed on Jan. 6, 2000, now Pat. No. 7,257,714.
Application No. 09/478,720 is a continuation-in-part of application No. 09/366,976, filed on Aug. 4, 1999, now Pat. No. 6,547,130.

(51) Int. Cl. H01L 23/495; H01L 21/56

(52) U.S. Cl. 257/666; 438/108; 257/E21.502; 257/E23.031

(57) ABSTRACT

Portable electronic storage device (PESD) manufacturing methods utilizing lead frames are described. According to one exemplary embodiment, a process of manufacturing core unit of PESD comprises: producing a processed flash memory IC chip with several metal contact pads and at least one passive component located on top layer; pre-fabricating a lead frame having opposing first and second surfaces, a plurality of metal connectors disposed on the first surface and a cavity through both surfaces; attaching the top layer of the processed flash memory IC chip onto the first surface such that the metal connectors are electrically connected to the respective metal contact pads and the cavity provides an non-conductive space for the at least one passive component; and forming a molded enclosure on both surfaces of the lead frame to form a core unit, the mold enclosure is configured such that the connectors are exposed according to one of the PESD standards.

### CROSS-REFERENCE TO RELATED APPLICATIONS

This application is a continuation-in-part (CIP) of co-pending U.S. patent application Ser. No. 11/773,830, entitled “Molding Methods to Manufacture Single-Chip On-Board USB Device” filed on Jul. 5, 2007.

This application is also a CIP of co-pending U.S. patent application Ser. No. 11/831,888, entitled “Molding Methods to Manufacture Single-Chip On-Board MMC/SD Device” filed on Jul. 31, 2007.

Each of the parent applications (U.S. patent application Ser. No. 11/773,830 and 11/831,888) is a CIP of U.S. patent application Ser. No. 11/309,594 for “Single-chip Multi-Media Card/Secure Digital (MMC/SD) Controller Reading Power-on Boot Code from Integrated Flash Memory for User Storage”, filed on Aug. 28, 2006, which is a CIP of U.S. application Ser. No. 10/707,277 for “Single-Chip USB Controller Reading Power-on Boot Code from Integrated Flash Memory for User Storage”, filed on Dec. 2, 2003, now U.S. Pat. No. 7,103,684.

This application is also a CIP of co-pending U.S. patent application Ser. No. 11/624,667, entitled “Electronic Data Storage Medium with Fingerprint Verification Capability”, filed on Jan. 18, 2007, which is a divisional application of U.S. patent application Ser. No. 09/478,720, filed on Jan. 6, 2000, which has been petitioned to claim the benefit of CIP status of one of inventor's earlier U.S. patent applications for “Integrated Circuit Card with Fingerprint Verification Capability”, U.S. application Ser. No. 09/366,976, filed Aug. 4, 1999, now issued as U.S. Pat. No. 6,547,130.

### FIELD OF THE INVENTION

The present invention relates to portable electronic storage devices (PESD), and more particularly to portable electronic storage devices such as those that utilize the Universal Serial Bus (USB), Multi-Media Card (MMC), Secure Digital (SD) and micro-SD (p-SD) specifications.

### BACKGROUND OF THE INVENTION

Portable electronic storage devices (PESD) have become widely accepted and used by consumers. In general, PESD are manufactured according to one of the standards (e.g., USB, MMC/SD, or micro-SD) and made of a core unit inside a plastic or metal casing. The core unit includes flash memory and controller attaching to a printed circuit board (PCB). Flash memory uses electrically-erasable programmable read-on memory (EEPROM) as the non-volatile storage that can store large amount of data (e.g., 128 Megabytes or more). The controller is configured to provide data traffic to and from the flash memory.

Due to similarities between the MMC and SD standards (e.g., form factors and construction, locations of connectors, contact pads, etc.), MMC and SD cards are collectively referred to herein as “MMC/SD” cards unless separately specified.

A typical prior art manufacturing process of core unit of PESD is shown in FIG. 1. The process starts with producing or procuring a chip wafer 100, which contains a number of flash memory dies 104. Each of the dies 104 is configured such that contact pads for power and signals are routed to the middle of the die 104. Next, a custom made PCB 102 is produced. The PCB 102 includes an open slot with a plurality of bonding fingers for conductive paths. The open lot is located at the middle of the PCB 102. The custom designed PCB 102 is later glued to the flash memory die 104. In other words, the bottom surface of the PCB is attached to the top layer of the memory die 104. In order to access the contact pads, the open slot is aligned with respect to the contact pads of the flash memory die 104.

After the PCB 102 and the flash memory die 104 are attached together, a delicate process of wire bonding is performed to connect the contact pads to the bond fingers with metal wires (e.g., gold or aluminum wires). Then the combined PCB and flash memory die is molded into a single piece housing (e.g., plastic). Finally, a ball grid array of solders is applied to various locations of the conductive paths for attaching other required components (e.g., controller).

As the trend of creating ever smaller PESD prevails, the PCB 102 needs to be as small as possible. However, relatively large number of solders in the ball grid array would create a big challenge in the manufacturing process. For example, solders cannot be overlapped with each other. In addition, not only more solders need to be applied in a relative small surface, same number of metal wires need to be wire bonded between the flash memory die 104 and the PCB 102. In the example shown in FIG. 1, there are sixty (60) solders. It would need to layout a PCB with a size substantially larger than the flash memory die to properly accommodate that many solders. Furthermore, the larger number of wires needs to be wire bonded, the higher manufacturing costs would incur.

Given the foregoing drawbacks and limitations of the prior art, it would be desirable to have improved manufacturing processes of core unit of PESD.

### BRIEF SUMMARY OF THE INVENTION

This section is for the purpose of summarizing some aspects of the present invention and to briefly introduce some preferred embodiments. Simplifications or omissions in this section as well as in the abstract and the title herein may be made to avoid obscuring the purpose of the section. Such simplifications or omissions are not intended to limit the scope of the present invention.

Methods of manufacturing portable electronic storage device utilizing lead frame connectors are disclosed According to one aspect of the present invention, a rerouting process of a chip wafer containing flash memory integrated circuit (IC) dies is performed to ensure contact pads are routed to the top layer of each of the flash memory IC dies. Passive components (e.g., resistors, capacitors, oscillators, and light emitting diodes) and optional controller die are mounted on each of the flash memory IC dies using surface mounting technologies (e.g., a flip chip technology, chip scale packaging) to create a processed flash memory IC chip. Then the chip wafer is diced into individual processed chips in a singulation process.

In another aspect of the present invention, a panel of custom designed lead frames is configured and produced to provide metal connectors (e.g., gold plated connectors) for the processed flash memory IC chip to be attached thereon. The number and orientation of the metal connectors are configured according to specific type of PESD, for example, USB is four (4), micro-SD eight (8) and MMC/SD nine (9). Attachment between the processed flash memory IC chip and the lead frame uses a surface mount technology.

According to yet another aspect, core units are formed by a molding process to encase the attached lead frame and processed flash memory IC chip. Because of chip scale packaging employed in the present invention, the final core unit is substantially near the size of the flash memory IC die.

According to yet anther aspect, a core unit of PESD manufactured with the process of the present invention comprises IC die and lead frame connectors encased in a molded enclosure without any print circuit board (PCB) and without costly wire bonding process.

According to one embodiment of the present invention, a process of manufacturing core unit of PESD comprises: producing a processed flash memory IC chip with several metal contact pads and at least one passive component located on top layer; pre-fabricating a lead frame having opposing first and second surfaces, a plurality of metal connectors disposed on the first surface and a cavity through both surfaces; attaching the top layer of the processed flash memory IC chip onto the first surface such that the metal connectors are electrically connected to the respective metal contact pads and the cavity provides an non-conductive space for the at least one passive component; and forming a molded enclosure on both the first and second surfaces to form a core unit such that the metal connectors are exposed in accordance with one of the standards such as USB, MMC/SD or micro-SD.

The above process further includes rerouting the metal contact pads to the top layer of all of the flash memory IC dies in a chip wafer using at least two layers of mask; attaching the at least one passive component to the respective metal contact pads on the top layer; and dicing the chip wafer into a plurality of the processed flash memory IC chips.

One of the objects, features, and advantages of the present invention is to allow core units of PESD be manufactured in smallest possible size (i.e., substantially near the size of flash memory IC die) using chip scale package technology. Other objects, features, and advantages of the present invention will become apparent upon examining the following detailed description of an embodiment thereof, taken in conjunction with the attached drawings.

### BRIEF DESCRIPTION OF THE DRAWINGS

These and other features, aspects, and advantages of the present invention will be better understood with regard to the following description, appended claims, and accompanying drawings as follows:

FIG. 1 is a schematic diagram showing a prior art manufacturing procedure of a core unit of portable electronic storage devices (PESD);

FIG. 2 is a flow chart illustrating an exemplary manufacturing process of producing core unit of portable electronic storage devices (PESD) utilizing lead frame connectors in accordance with one embodiment of the present invention;

FIG. 3A is a diagram depicting a chip wafer having a plurality of flash memory integrated circuit (IC) dies with flash memory logic and controller logic integrated therein after rerouting operation of the manufacturing process of FIG. 2 for USB based PESD;

FIG. 3B is a diagram depicting another chip wafer having a plurality of alternative flash memory IC dies with only flash memory logic embedded therein after rerouting operation of the manufacturing process of FIG. 2 for USB based PESD;

FIG. 4 is a diagram showing one of the alternative flash memory IC dies of FIG. 3B and a corresponding lead frame (including connectors) used for manufacturing USB core unit in the process of FIG. 2 for USB based PESD;

FIG. 5 is a diagram showing perspective views of the lead frame of FIG. 4, each having one alternative flash memory IC die attached thereon in the process of FIG. 2 for USB based PESD;

FIG. 6 is a perspective view showing an exemplary arrangement of a panel of a plurality of lead frames of FIG. 5 utilized for manufacturing core units in the process of FIG. 2 for USB based PESD;

FIG. 7 is a diagram showing a top and a bottom perspective view of a plurality of USB core units connected by support frames to the lead frame panel after the molding operation in the manufacturing process of FIG. 2 for USB based PESD;

FIG. 8 is a diagram showing top and bottom perspective views of a USB core unit after singulation operation in the manufacturing process of FIG. 2 for USB based PESD;

FIG. 9A is a diagram depicting a chip wafer having a plurality of flash memory IC dies with flash memory logic and controller logic integrated therein after rerouting operation of the manufacturing process of FIG. 2 for micro-SD based PESD;

FIG. 9B is a diagram depicting a wafer having a plurality of alternative flash memory IC dies with only flash memory logic embedded therein after rerouting operation of the manufacturing process of FIG. 2 for micro-SD based PESD;

FIG. 10 is a diagram showing one of the alternative flash memory IC dies of FIG. 9B and a corresponding lead frame (including connectors) used for manufacturing core unit in the process of FIG. 2 for micro-SD based PESD;

FIG. 11 is a diagram showing perspective views of the lead frame of FIG. 10, each having one alternative flash memory IC die attached thereon in the process of FIG. 2 for USB-based PESD;

FIG. 12 is a diagram showing top and bottom perspective views of a plurality of micro-SD core units connected by support frames to a lead frame panel after plastic molding operation in the manufacturing process of FIG. 2 for micro-SD based PESD;

FIG. 13 is a perspective view of a micro-SD core unit after singulation operation in the manufacturing process of FIG. 2 for micro-SD based PESD;

FIG. 14A is a diagram depicting a wafer having a plurality of flash memory IC dies with flash memory logic and controller logic integrated therein after rerouting operation of the manufacturing process of FIG. 2 for MMC/SD based PESD;

FIG. 14B is a diagram depicting a wafer having a plurality of alternative flash memory IC dies with only flash memory logic embedded therein after rerouting operation of the manufacturing process of FIG. 2 for MMC/SD based PESD;

FIG. 15 is a diagram showing one of the alternative flash memory IC dies of FIG. 14B and a corresponding lead frame (including connectors) used for manufacturing MMC/SD core unit in the process of FIG. 2 for MMC/SD based PESD;

FIG. 16 is a diagram showing top and bottom perspective views of the lead frame of FIG. 15, each having one alternative flash memory IC die attached thereon in the process of FIG. 2 for micro-SD based PESD;

FIG. 17 is a diagram showing top and bottom perspective views of a plurality of MMC/SD core units connected by support frames to a lead frame panel after plastic molding operation in the manufacturing process of FIG. 2 for MMC/SD based PESD;

FIG. 18A is a perspective view of a MMC/SD core unit after singulation operation in the manufacturing process of FIG. 2 for MMC/SD based PESD;

FIG. 18B is a perspective view of another MMC core unit after singulation operation in the manufacturing process of FIG. 2 for MMC/SD based PESD; and

FIG. 19 is a set of perspective views of ultrasonic press procedure to assemble the MMC/SD core unit of FIG. 18A into a final SD assembly, according to an embodiment of the present invention.

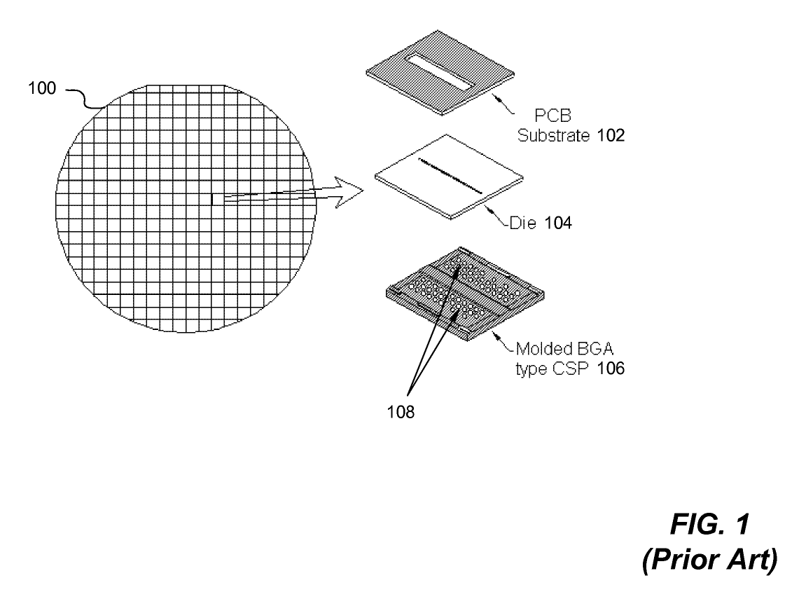

### DETAILED DESCRIPTION

In the following description, numerous specific details are set forth in order to provide a thorough understanding of the present invention. However, it will become obvious to those skilled in the art that the present invention may be practiced without these specific details. The descriptions and representations herein are the common means used by those experienced or skilled in the art to most effectively convey the substance of their work to others skilled in the art. In other instances, well-known methods, procedures, components, and circuitry have not been described in detail to avoid unnecessarily obscuring aspects of the present invention.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments mutually exclusive of other embodiments. Used herein, the terms “upper”, “lower”, “top”, “bottom”, “middle”, “upwards”, and “downwards” are intended to provide relative positions for the purposes of description, and are not intended to designate an absolute frame of reference. Further, the order of blocks in process flowcharts or diagrams representing one or more embodiments of the invention do not inherently indicate any particular order nor imply any limitations in the invention.

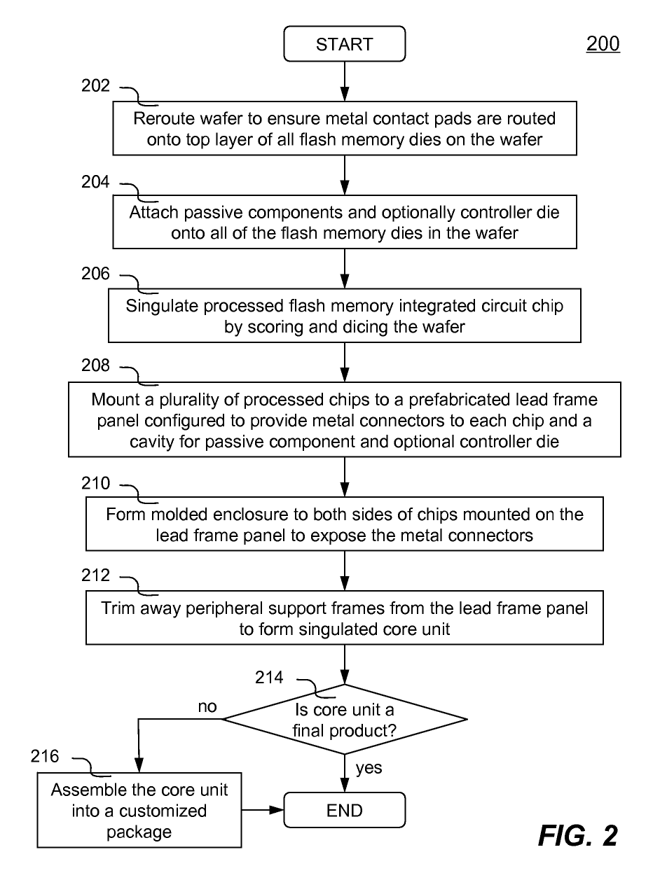

Embodiments of the present invention are discussed herein with reference to FIGS. 2-19. However, those skilled in the art will readily appreciate that the detailed description given herein with respect to these figures is for explanatory purposes as the invention extends beyond these limited embodiments.

USB Based PESD

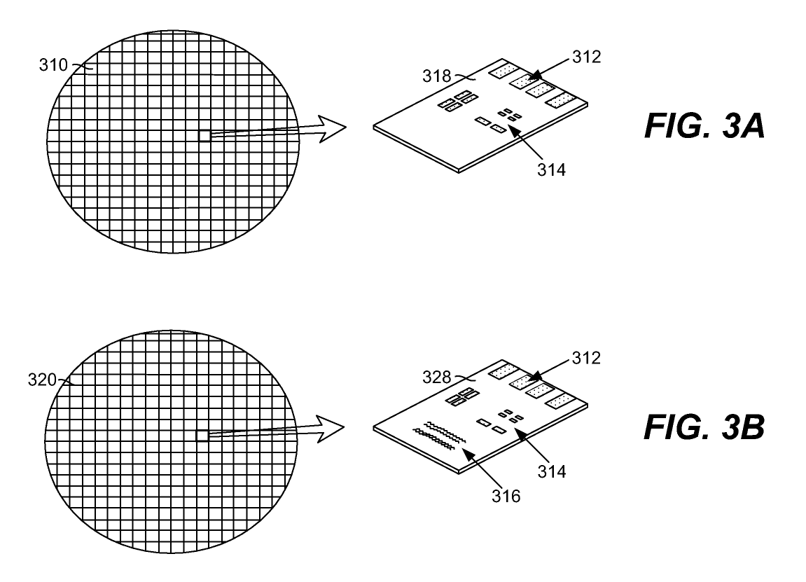

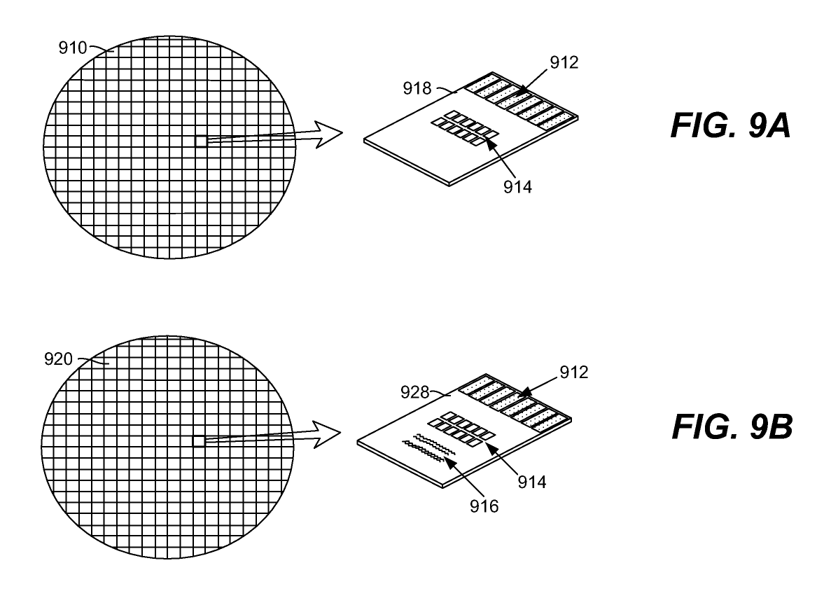

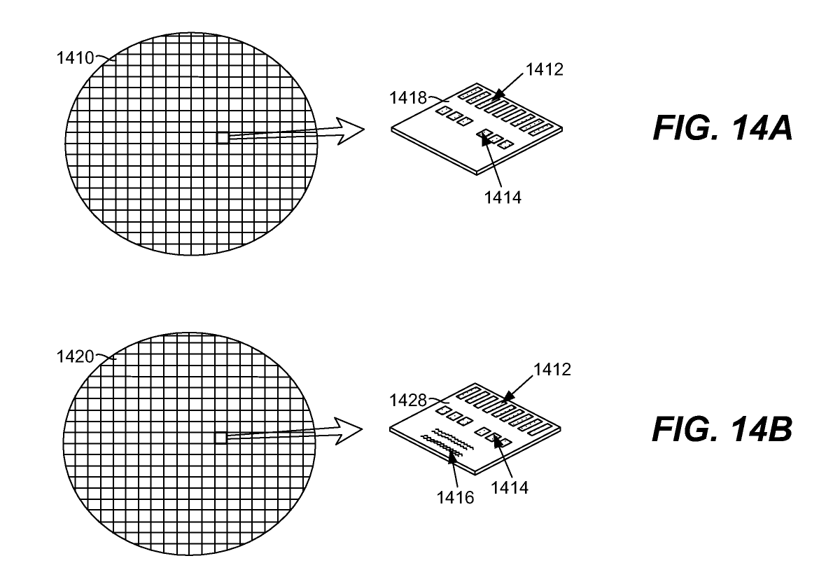

Referring now to the drawings, in which like numerals refer to like parts throughout several views. FIG. 2 shows a flow chart of an exemplary manufacturing process 200 of a portable electronic storage device (PESD) utilizing lead frame connectors in accordance with one embodiment of the present invention. The process 200 is preferably understood with FIGS. 3A-19, in particular, FIGS. 3A-8 for USB based PESD, FIGS. 9A-13 for micro-SD based PESD and FIGS. 14A-19 for MMC/SD based PESD.

Process 200 starts at step 202 by rerouting a flash memory chip wafer (wafer 310 of FIG. 3A or wafer 320 of FIG. 3B) to ensure metal contact pads (e.g., contact pads for transmitting signals and power) of all flash memory integrated circuit (IC) dies to be located on top layer. In one embodiment, the flash memory IC die (e.g., die 318 of FIG. 3A) includes flash memory and controller logic or circuits embedded therein. A first group 312 of contact pads located at top edge of the flash memory IC die 318 is configured to be connected to metal connectors to form an electrical conductive path, while the second group 314 of contact pads located in the middle is configured for at least one passive component 325. A typical passive component 325 includes, but is not limited to, a resistor, a capacitor, an oscillator and a light emitting diode.

In an alternative embodiment, the flash memory IC die (e.g., die 328 of FIG. 3B) includes flash memory logic or circuits only. Similar to IC die 318, there are first and second groups of contact pads for the alternative IC die 328. In addition, a third group 318 of contact pads located in lower portion of the flash memory IC die 328 is configured to be attached to a controller die 326. Step 202 may be accomplished with two or more layers (e.g., two to four layers) of mask depending on the complexity of the flash memory IC die and on which specific type of PESD to be manufactured.

Next, at step 204, at least one passive component 325 is attached to the second group 314 of contact pads on the top layer of each of the flash memory IC dies 318 or 328 in the wafer 310 or 320 to create a process flash memory IC chip. In the alternative embodiment, a controller die 326 is attached to the third group 316 of contact pads in additional to the at least one passive component 325.

In one embodiment, attaching a controller die 326 to a flash memory IC die 328 is accomplished using flip chip technology. Flip chip technology is one type of mounting used for semiconductor devices, which does not require any wire bonds. Instead the final wafer processing step deposits solder bumps on the chip contact pads, which are used to connect directly to the associated external circuitry (e.g., chip or die). This mounting technology is also known as the Controlled Collapse Chip Connection, or C4.

In typical semiconductor manufacturing systems, dies are built up in large numbers on a single large “wafer” of semiconductor material, typically silicon. The individual dies are patterned with small pads of metal near their edges that serve as the connections to an eventual mechanical carrier. The dies are then cut out of the wafer and attached to their carriers, typically with small wires. These wires eventually lead to pins on the outside of the carriers, which are attached to the rest of the circuitry making up the electronic system.

The processing of a flip chip is similar to conventional IC fabrication with a few additional steps. Near the end of the process the contact pads are “metalized” to make them more suitable for being soldered onto. A small dot of solder is then deposited on each of the pads. The dies are then cut out of the wafer as normal. No additional processing is required, and there is no mechanical carrier at all. To attach the flip chip into a circuit (e.g., another IC chip), it is inverted to bring the solder dots down onto connectors on the underlying electronics, circuit board or another die. The solder is then re-melted to produce an electrical connection, typically using an ultrasonic process. This also leaves a small space between the chip's circuitry and the underlying mounting. In most cases an electrically-insulating adhesive is then “underfilled” to provide a stronger mechanical connection, provide a heat bridge, and to ensure the solder joints are not stressed due to differential heating of the chip and the rest of the system. The resulting completed assembly is much smaller than a traditional carrier-based system; the chip sits directly on anther chip, and is much smaller than the carrier both in area and height.

The chip wafer described herein can be either fabricated or procured as long as the chip wafer is manufactured to include flash memory logic and optional controller logic based upon one of the desired specifications for manufacturing PESD.

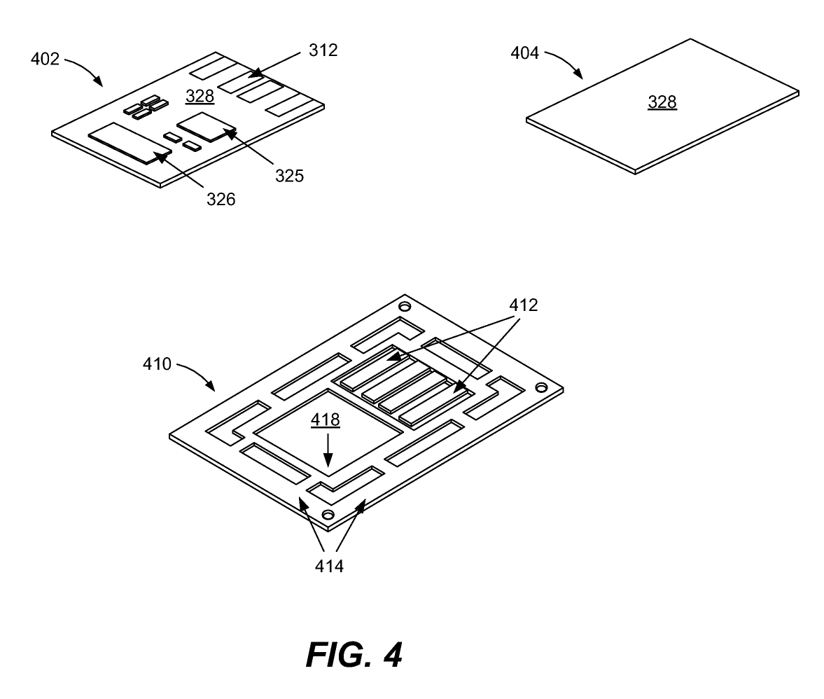

Referring back to step 206, the processed flash memory IC chip is singulated from the chip wafer 310 or 320 via a standard scoring and dicing procedure. Only the dies passed quality control are kept. A top layer perspective view 402 and a bottom layer perspective view 404 of a singulated processed flash memory IC chip 328 (i.e., alternative embodiment) are shown in FIG. 4. Mounted on the chip 328 are at least one passive component 325 and a controller die 326.

At step 208, the processed flash memory IC chip is mounted onto a prefabricated lead frame (e.g., lead frame 410 of FIG. 4). The lead frame 410 is prefabricated according to specific customer requirements. In this embodiment, the lead frame 410 is configured to provide metal connectors to the processed flash memory IC chip 328 in accordance with the USB specification. The lead frame 410 comprises a plurality of metal connectors 412 (e.g., four (4) connectors), a cavity or opening 418 and peripheral support frames 414.

When the processed flash memory IC chip is mounted on the lead frame, the first group of metal contact pads 312 is attached to the metal connectors 412 on the lead frame 410. In other words, the attachment is made by connecting the top layer of the processed flash memory chip against the lead frame using any of suitable surface mount technologies. For example, solders are first applied to the first group of contact pads before orientating the processed flash memory IC chip to be mounted on. A conductive path is created in this mounting step to ensure signals and power can be transmitted via the metal connectors to and from the processed flash memory IC chip.

A lead frame or leadframe is used in semiconductor IC package, providing mechanical support to the die during the assembly into a final product. Traditionally lead frame comprises die paddle and leads. The die paddle is used for attaching to the die, while the leads are used as the external electrical connections to the outside world (i.e., outside the final package). There are a number of ways for connecting the die to the leads. According to one embodiment of the present invention, the attachment of a die to a lead frame employs a surface mounting technology.

Lead frames are made of metals that meet the following critical properties: good adherence to the molding compound, a coefficient of thermal expansion as close as possible to those of the die and the molding compound, high strength, good formability, and high electrical and thermal conductivities. Alloy 42 or copper is an example of such a metal.

Lead frames are constructed from flat sheet metal either by stamping or etching. Stamping is a highly-automated mechanical process that employs die and punch sets to progressively achieve the intended lead frame structure through a series of stamping/punching steps.

Etching comprises of selectively covering the sheet metal with photoresist in accordance with the pattern of the lead frame. The sheet metal is then exposed to chemical etchants that remove areas not covered by photoresist. After the etching process, the ‘etched’ frames are cut into strips. The strip may contain more than one lead frame. Such a strip is referred to as a lead frame panel in this document.

After stamping or etching, the lead frame is then finished with cleaning, gold-plating, taping and downsetting steps. Gold-plating is done on the bonding fingers and die pad to improve die attach quality. Taping comprises of putting a lead lock tape over the leads to prevent lead deformation, while downsetting comprises of pushing the die paddle down relative to the bonding fingers in compliance with standard industry requirements.

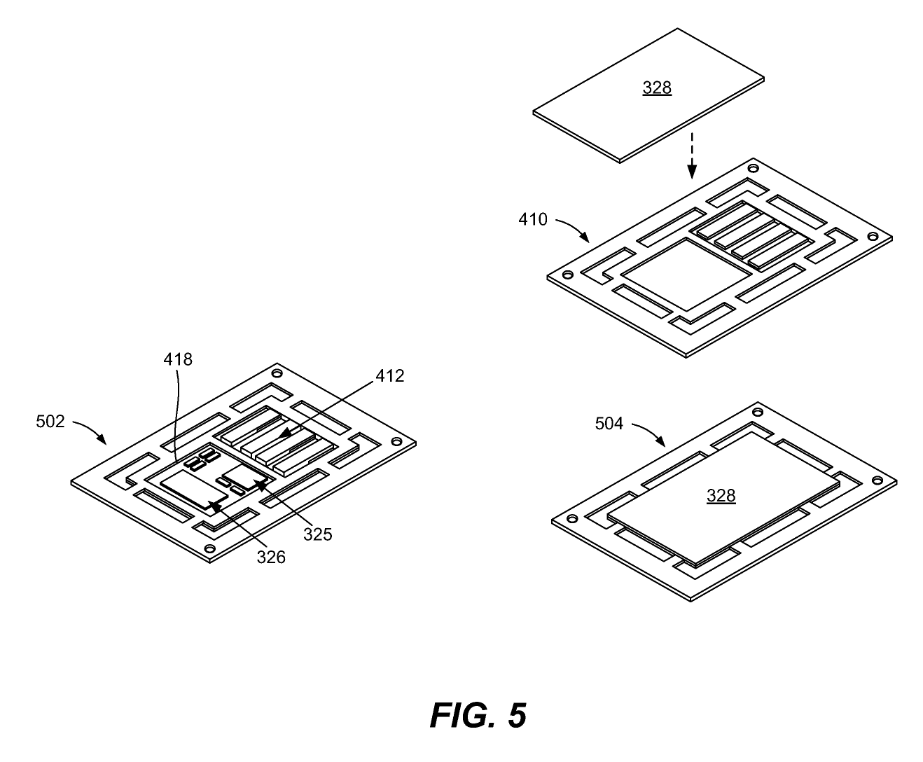

The mounting step 208 of process 200 is illustrated in FIG. 5, in which an exploded view showing the processed flash memory IC chip 328 with the top layer (not shown) facing the pre-fabricated lead frame 410 in the attachment process. At the end of step 208, the connected chip and lead frame are shown in a top perspective view 502 and in a bottom perspective view 504. The bottom view 504 reflects the facts that the bottom layer of the processed flash memory IC chip is flat with no other components attached thereto. The top view 502 shows that the metal connectors 412 (e.g., four (4) gold plated connectors in accordance with the USB specification) and the cavity or hole 418 providing non-conductive space for the at least one passive component 325 and the optionally attached controller die 326. When the controller logic or circuits are integrated or built in within the flash memory IC die (e.g., die 318 of FIG. 3A), there is no need for the controller die 326.

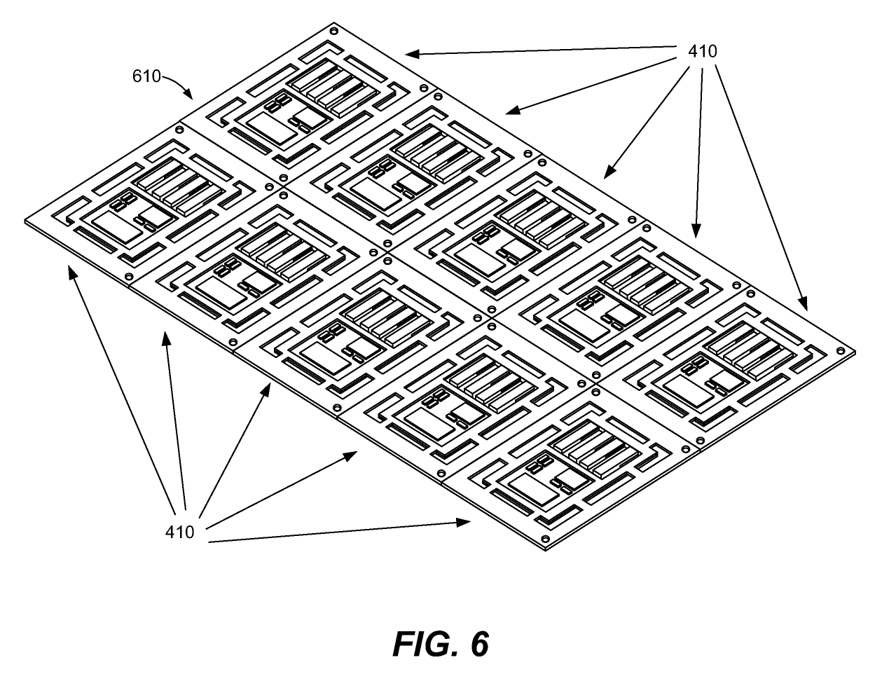

In order to volume produce PESD, the lead frame 410 is not produced one at a time, instead a panel of more than one of the lead frame 410 is prefabricated. For example, a 2×5 lead frame panel 610 comprises ten (10) lead frames 410 in a two-row arrangement. FIG. 6 is a perspective view illustrating the lead frame panel 610 after the mounting step 208.

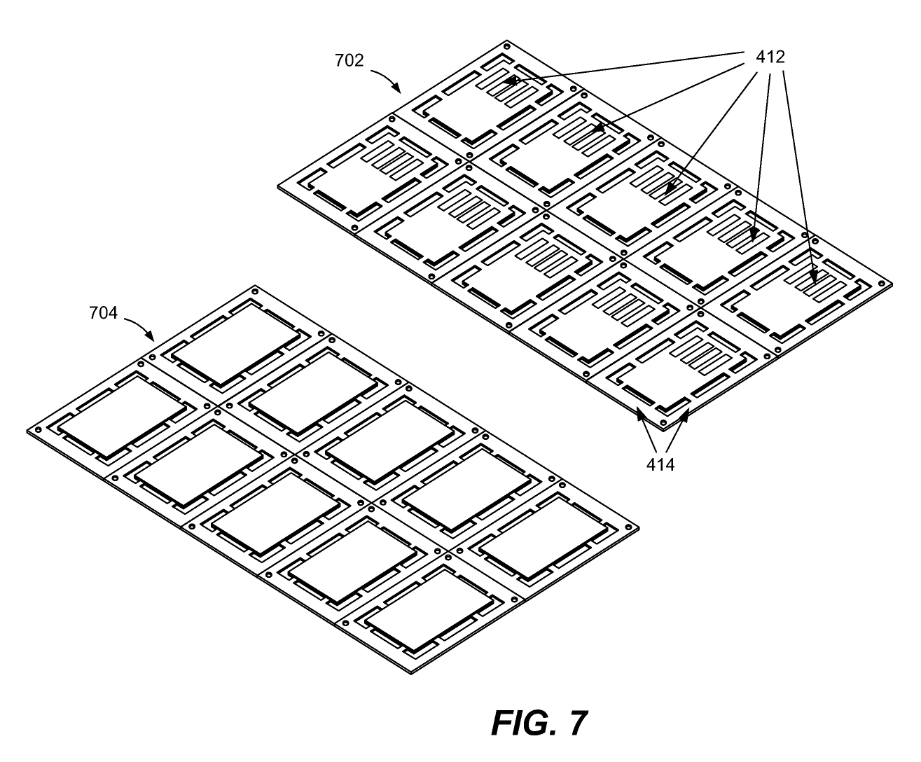

The next step 210 of process 200 is to form a molded enclosure that encases both sides of the connected processed flash memory IC chip and the lead frame panel 610 with suitable material (e.g., plastic or ceramic). The forming of molded enclosure is performed with suitable means that have been practiced by those of ordinary skilled in the art of semiconductor manufacturing. Shown in FIG. 7 are top 702 and bottom 704 perspective views of the lead frame panel 610 of FIG. 6 after step 210. All of the supported frames 414 are still connected at this stage of the process 200. The molded enclosure has only the metal connectors 412 exposed.

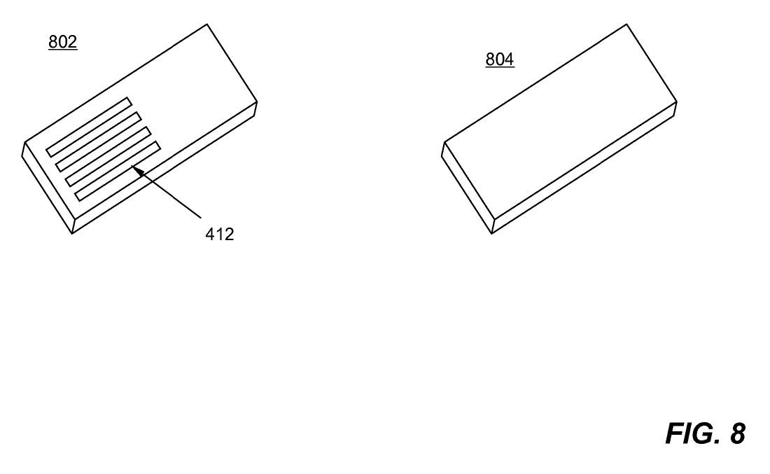

The process 200 then moves to step 212, in which the support frames 414 from the lead frame panel 610 are trimmed away to produce individual core units. FIG. 8 shows top 802 and bottom 804 perspective views depicting a core unit at the end of step 212 based on the USB specification. Metal connectors 412 are exposed to be electrically connected in a receptacle of a PESD reader (e.g., a USB reader). Next the process 200 moves to a decision 214, in which it is determined whether the core unit produced at the end of step 212 is a final product. If “yes”, the process 200 ends. Otherwise, the process 200 follows the “no” path to step 216 to assemble the core unit into a customized package as the final product before ending. There are numerous methods to customize the final product. For example, embedded a core unit in a consumer products such a key chain.

Using the manufacturing process disclosed in the present invention to produce PESD is more cost-effective due to at least the following factors: 1) no printed circuit board (PCB); 2) no wire bonding; and 3) a lead frame with lower cost surface mount technology. Thereby, the present invention overcomes the shortcomings of prior art approaches.

Micro-SD Based PESD

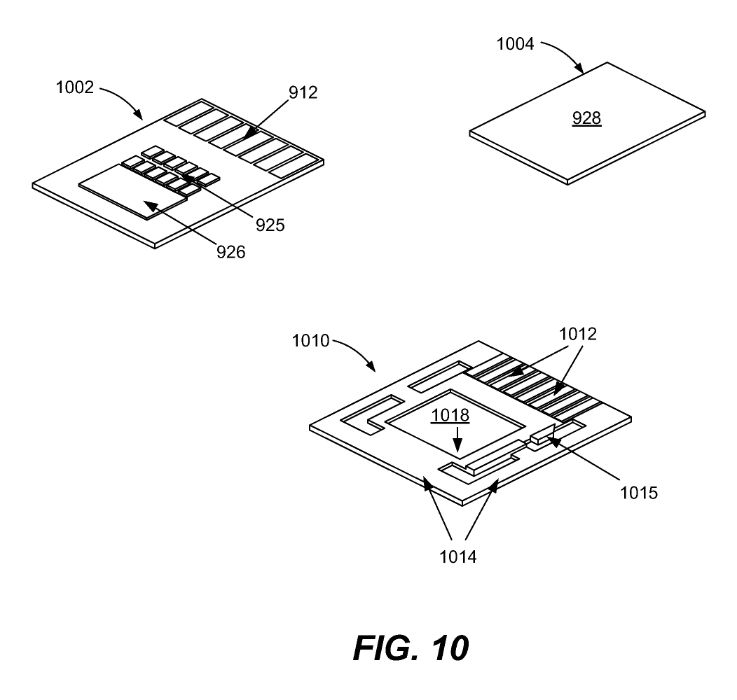

Referring now to FIGS. 9A-13, these figures, substantially similar to FIGS. 3A-8, show another embodiment of the exemplary manufacturing process 200 of FIG. 2 for micro-SD based PESD. FIGS. 9A and 9B show two chip wafers with alternative flash memory IC dies (die 918 with controller logic and die 928 without controller logic built-in) in blow-up views. A first group of metal contact pads 912 comprises eight (8) connector pads. A second group 914 for passive components and a third 916 for an optional controller die. FIG. 10 shows top 1002 and bottom 1004 perspective views of the processed flash memory IC chip. Shown in view 1002, a controller die 926 is mounted on the chip 928 along with at least one passive component 925. Also shown in FIG. 10 is a lead frame 1010, which comprises eight (8) gold-plated connectors 1012, a cavity or hole 1018, support frames 1014 and a security tab 1015 for micro-SD.

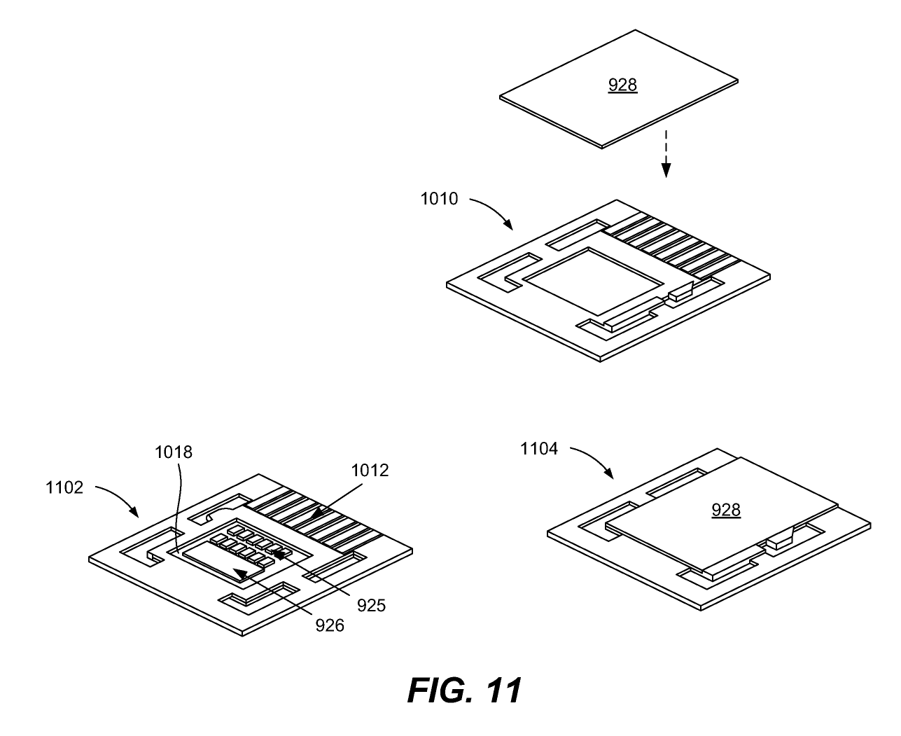

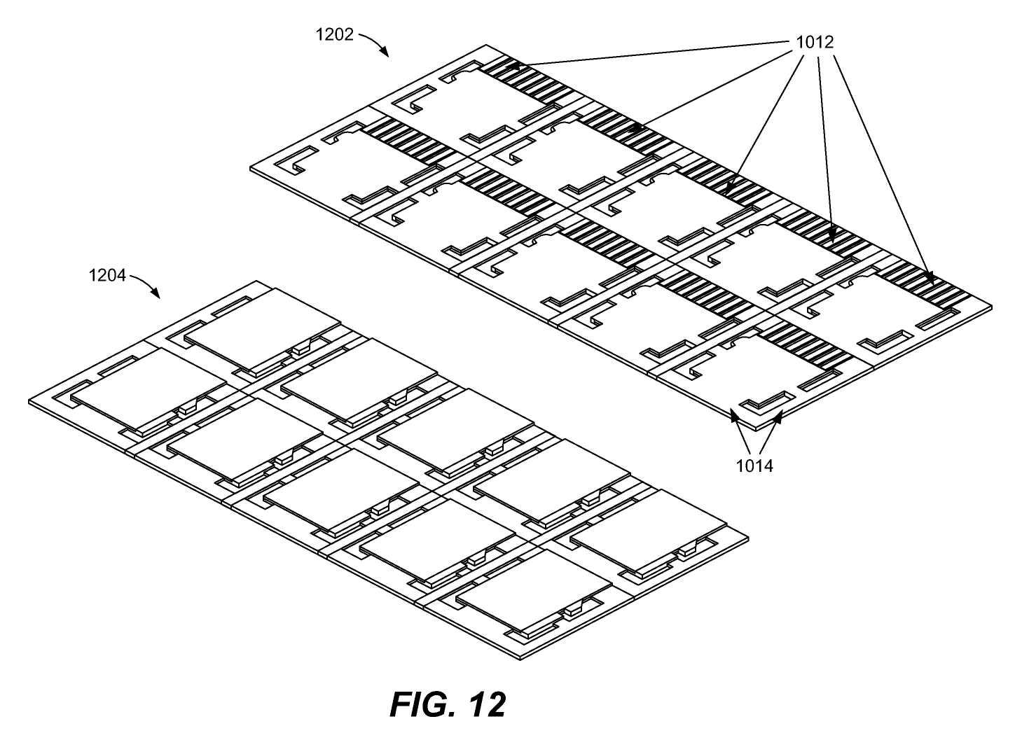

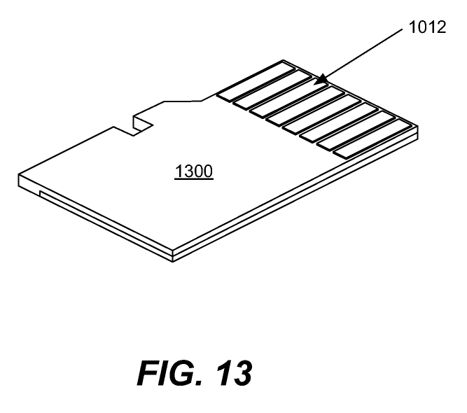

FIG. 11 shows an exploded view showing how the processed flash memory IC chip 928 is attached to the lead frame 1010 using surface mount technique. Top 1102 and bottom 1104 perspective views illustrate the configuration after the attachment. The top view 1102 shows the metal connectors 1102 are exposed, and the at least one passive component 925 and the optional controller die 926 are placed in a non-conductive space formed by the cavity 1018. FIG. 12, similar to FIG. 7, shows top 1202 and bottom 1204 perspective views of a lead frame panel after molded enclosure has been formed over both sides of the connected processed flash memory IC chip 928 and lead frame panel. At this stage of the manufacturing process, all of the support frames 1014 are still connected. In this example, a 2×5 (two rows of 5 pairs) lead frame panel is used in manufacturing micro-SD based PESD. Finally, FIG. 13 depicts a core unit 1300 for the micro-SD based PESD. If the core unit 1300 is a final product, no further process is required. Each core unit 1300 is produced by trimming away the support frames 1014 from the lead frame panel in a singulation process.

MMC/SD Based PESD

FIGS. 14A-19 illustrate yet another embodiment of the present invention using the exemplary manufacturing process 200 of FIG. 2 for the MMC/SD based PESD. Again, these figures are substantially similar to FIGS. 3A-8. Since MMC and SD based PESD can share same core unit, the process for these two specifications are exact the same.

Similar to FIGS. 3A and 3B, FIGS. 14A and 14B show two chip wafers 1410 and 1420. A flash memory IC die 1418 is shown in a blow-up view. Disposed on the top layer of the die 1418 are a first group of nine (9) metal contact pads 1412 for connectors and a second group of contact pads for passive components 1414. The die 1418 has both flash memory and controller logic embedded therein, while the die 1428 has only flash memory logic included. Thereby a third group of contact pads 1416 for a controller die is disposed on the top layer of the flash memory IC die 1428.

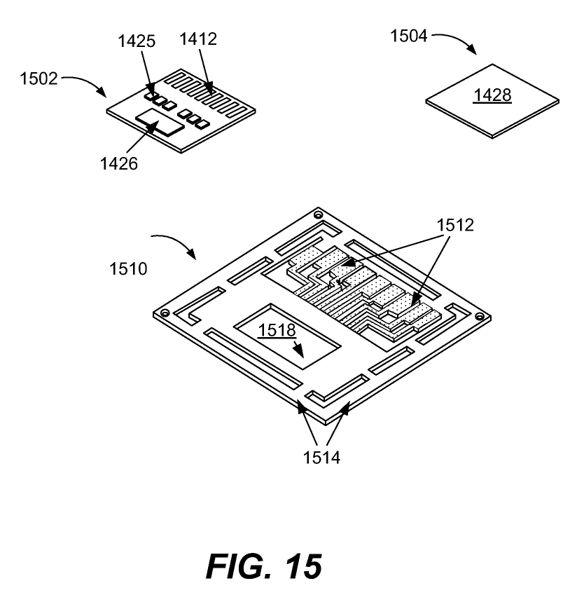

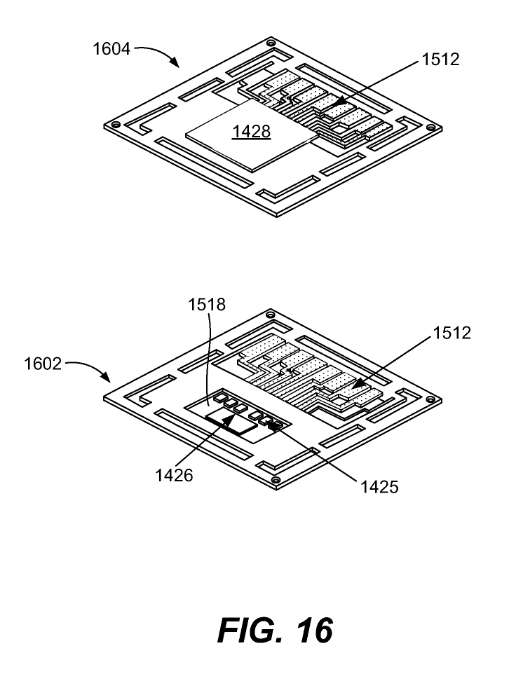

Shown in FIG. 15 are top 1502 and bottom 1504 perspective views of a processed memory IC chip. In the bottom view 1504, the bottom layer of the flash memory IC die 1428 is shown. The top view 1502 shows nine (9) metal contact pads 1412, at least one passive component 1425 and an optional controller die 1426. Also shown in FIG. 15 is a lead frame 1510, which includes nine (9) metal connectors 1512, a cavity 1518 and support frames 1514. Due to the dimension specified in MMC/SD standard, the metal connectors 1512 include extended fingers (e.g., gold-plated fingers). After the processed chip has been mounted on the lead frame 1510, the configuration is illustrated in FIG. 16. A top perspective view 1602 shows exposed metal connectors 1512 with the at least one passive components 1425 and the controller die 1426 located in a non-conductive space provided by the cavity 1518. The bottom view 1604 shows the exposed metal connectors 1512 and the bottom layer of the flash memory IC die 1428.

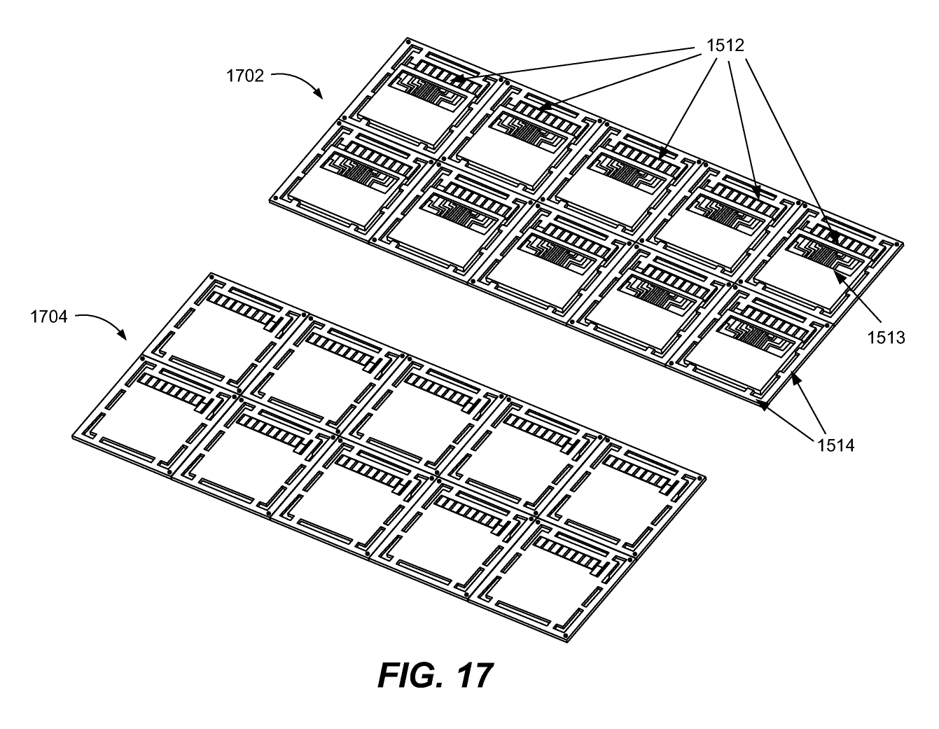

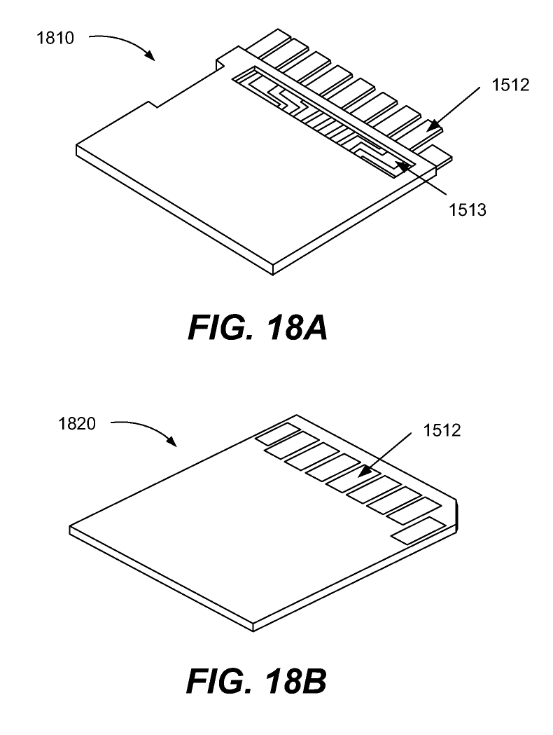

FIG. 17, similar to FIG. 12, depicts a configuration of the manufacturing process after forming molded enclosure. A lead frame panel with two rows of five pairs of the lead frame is used. In bottom view 1704, only the metal connectors are exposed. Top view 1702 shows an opening slot 1513 in additional to the exposed metal connectors 1512. At this stage, all core units are still connected by the support frames 1514. In a singulation operation, the support frames 1514 are cut away. A MMC/SD core unit 1810 is shown in FIG. 18A. The exposed connectors 1512 and the open slot 1513 are also shown. The open lot 1513 provides access of the metal connectors 1512 to test equipment. One of the advantages is to avoid scratching on the metal connectors 1512 during testing. FIG. 18B shows an alternative MMC/SD core unit 1820 with only metal connectors 1512 exposed.

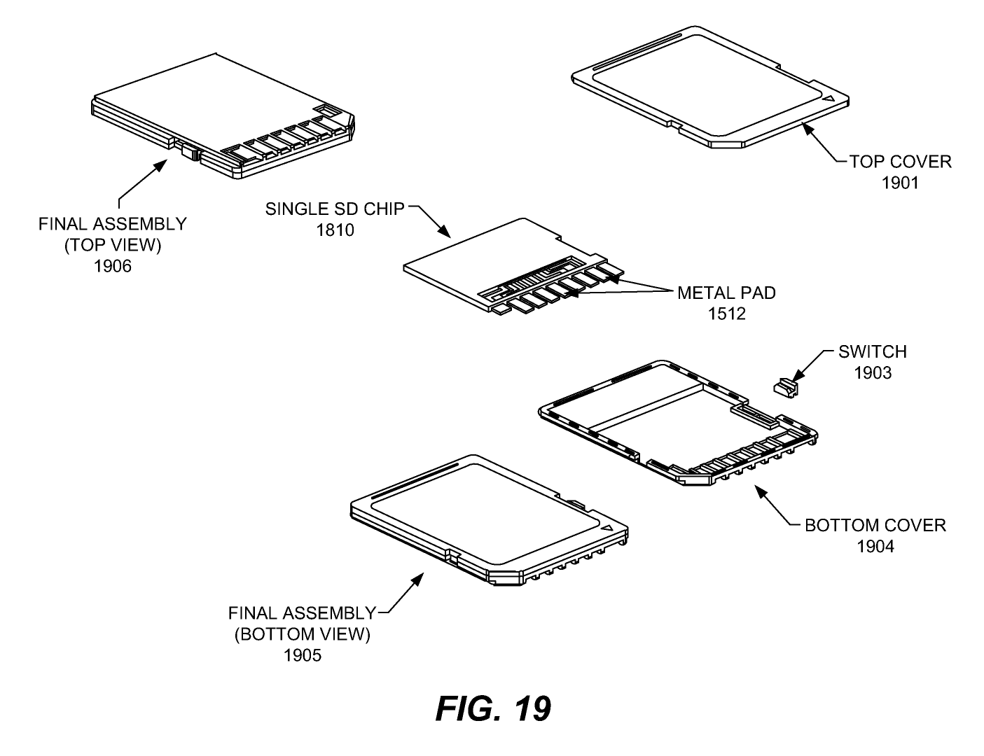

When the core unit 1810 is not a final product, a final assembly can be produced with an exemplary sequence shown in FIG. 19. A single core unit 1810 is placed between a top cover 1901 and a bottom cover 1904 with a switch 1903 attached on a specific location on the side wall. Once assembled, the final product is shown in top 1906 and bottom perspective views 1905. One typical method of assembling the final assembly uses ultrasonic press technology.

Although the present invention has been described with reference to specific embodiments thereof, these embodiments are merely illustrative, and not restrictive of, the present invention. Various modifications or changes to the specifically disclosed exemplary embodiments will be suggested to persons skilled in the art. For example, whereas the exemplary manufacturing process has been shown and described to produce portable electronic storage devices (PESD) with certain specifications, PESD based on other specifications may also be manufactured. In summary, the scope of the invention should not be restricted to the specific exemplary embodiments disclosed herein, and all modifications that are readily suggested to those of ordinary skill in the art should be included within the spirit and purview of this application and scope of the appended claims.

What is claimed is:

1. A process of manufacturing core unit of a portable electronic storage device (PESD) comprising:
producing a processed flash memory integrated circuit (IC) chip with a plurality of metal contact pads and at least one passive component located on top layer;
pre-fabricating a lead frame having opposing first and second surfaces, a plurality of metal connectors disposed on the first surface and a cavity or hole through both the first and second surface;
attaching the top layer of the processed flash memory IC chip onto the first surface such that the metal connectors are electrically connected to the respective metal contact pads and the cavity provides an non-conductive space for the at least one passive component; and
forming a molded enclosure on the both first and second surfaces to form a core unit, the mold enclosure is configured such that the metal connectors are exposed.

2. The process of claim 1, wherein the processed flash memory IC chip is adapted to include flash memory logic and controller logic.

3. The process of claim 2, wherein producing the flash memory IC chip comprising:
rerouting the metal contact pads to the top layer of all flash memory IC dies in a chip wafer with at least two layers of mask;
attaching the at least one passive component to the respective metal contact pads on the top layer; and
dicing the chip wafer into a plurality of the processed flash memory IC chips.

4. The process of claim 2, wherein the controller logic is integrated within the chip.

5. The process of claim 2, wherein the controller logic is provided by a controller die mounted on the top layer using flip chip technology.

6. The process of claim 5, wherein the controller die is positioned in the cavity after the processed flash memory IC chip is mounted on the lead frame.

7. The process of claim 1, wherein the at least one passive component comprise at least one of a resistor, a capacitor, an oscillator and a light emitting diode.

8. The process of claim 1, wherein the plurality of metal connectors in the lead frame is configured to conform to industry specifications for PESD.

9. The process of claim 1, wherein the molded enclosure provides an opening for testing equipment to probe the metal connectors without damaging the metal connectors.

10. The process of claim 1, wherein the lead frame contains peripheral support frames.

11. The process of claim 10, wherein producing the lead frame comprises producing a lead frame panel containing more than one of said lead frame.

12. The process of claim 11, further comprises trimming away all of the support frames from the lead frame panel to create singulated core unit after forming the molded enclosure.

13. The process of claim 12, wherein the core unit is further assembled into a customized package to form a portable electronic storage device.

14. An apparatus manufactured in accordance with the process of claim 1.

15. The subject matter of claim 14, wherein the apparatus is a Universal Serial Bus (USB) based flash memory device.

16. The subject matter of claim 14, wherein the apparatus is a micro Secure Digital (micro-SD) based flash memory device.

17. The subject matter of claim 14, wherein the apparatus is a Multi-Media Card/Secure Digital (MMC/SD) based flash memory device.

18. A portable electronic storage device comprising:
an integrated circuit (IC) means for providing flash memory logic and controller logic;
a lead frame, electronically attached to the IC means, providing a plurality of metal connectors; and
a molded enclosure means for encasing the IC means and the lead frame, the enclosure means is configured such that the metal connectors are exposed.

19. The device of claim 18, wherein the plurality of metal connectors is configured to transmit signals and power to and from the IC means.

20. The device of claim 18, wherein the plurality of metal connectors is configured to be outside interface to a computing device capable of transmitting signals and power to and from the device.
